(19) United States
(12) Patent Application Publication
(10) Pub. No.: US 2021/0265421 A1
(43) Pub. Date: Aug. 26, 2021

(54) THERMOELECTRIC CONVERSION MODULE

(71) Applicant: PANASONIC INTELLECTUAL PROPERTY MANAGEMENT CO., LTD., Osaka (JP)

(72) Inventors: Makiko TANAKA, Kyoto (JP); Satoshi MAESHIMA, Kyoto (JP); Daisuke SHIMIZU, Osaka (JP)

(21) Appl. No.: 17/316,182

(22) Filed: May 10, 2021

Related U.S. Application Data
(63) Continuation of application No. PCT/JP2019/043925, filed on Nov. 8, 2019.
(60) Provisional application No. 62/767,227, filed on Nov. 14, 2018.

(51) Int. Cl. H01L 27/16; H01L 35/08; H01L 35/32

(52) U.S. Cl. CPC H01L 27/16; H01L 35/16; H01L 35/32; H01L 35/08

(57) ABSTRACT

A thermoelectric conversion module includes: a first thermoelectric conversion element group including a first thermoelectric member including a first conductivity-type semiconductor, and a second thermoelectric member including a second conductivity-type semiconductor; a second thermoelectric conversion element group including a third thermoelectric member including the first conductivity-type semiconductor, and a fourth thermoelectric member including the second conductivity-type semiconductor; a first substrate connected to an upper side of the first thermoelectric conversion element group and the second thermoelectric conversion element group; and a second substrate connected to a lower side of the first thermoelectric conversion element group and the second thermoelectric conversion element group. The first thermoelectric member and the second thermoelectric member are electrically connected by a first current path. The third thermoelectric member and the fourth thermoelectric member are electrically connected by a second current path. The first current path is insulated from the second current path.

### CROSS REFERENCE TO RELATED APPLICATIONS

This application is a U.S. continuation application of PCT International Patent Application Number PCT/JP2019/043925 filed on Nov. 8, 2019, claiming the benefit of priority of U.S. Provisional Patent Application No. 62/767,227 filed on Nov. 14, 2018, the entire contents of which are hereby incorporated by reference.

### BACKGROUND

### 1. Technical Field

The present disclosure relates to a thermoelectric conversion module. The thermoelectric conversion module absorbs and dissipates heat by using the Peltier effect and applying direct current to a series circuit including P-type thermoelectric conversion elements and N-type thermoelectric conversion elements.

### 2. Description of the Related Art

As energy conversion technology using thermoelectric conversion, the Peltier cooling technology and the thermoelectric generation technology, for example, International publication No. 2018/143418, have been known conventionally. The Peltier cooling technology uses the Peltier effect to convert electrical energy into thermal energy. This technology is widely used, for example, for refrigerators, cooling semiconductor devices, and controlling the temperature of semiconductor laser oscillators. On the other hand, the thermoelectric generation technology uses the Seebeck effect to convert thermal energy to electrical energy. This technology is expected to be used in the field of energy harvesting to collect and utilize exhaust heat energy.

Meanwhile, with recent downsizing of Peltier devices, the thermoelectric generation technology is also attracting attention as haptic devices that create sensations of hot and cold in the fields of nursing care robots and haptic technology. The thermoelectric generation technology is also utilized in small-scale products such as beauty and health products, and development of smaller, more efficient devices has been demanded.

As such haptic devices that create sensations of hot and cold, a thermoelectric conversion device is used in which P-type and N-type thermoelectric conversion elements are connected alternately as a series circuit and sandwiched by two substrates from the up and down directions. For example, such a thermoelectric conversion device is used to apply only hot or cold stimulation, and a plurality of thermoelectric conversion devices are used adjacent to each other to apply both hot and cold stimulation.

### SUMMARY

However, for example, as such a haptic device that applies stimulation to part of the skin to create sensations of hot and cold, it is necessary to attach separate thermoelectric conversion devices for the respective hot stimulation and cold stimulation on a stimulation site to create sensations of hot and cold. Therefore, such thermoelectric conversion devices are not appropriate for haptics fields where portability is required and not appropriate for small products such as beauty devices, which need to save space.

In particular, regarding a haptic device that needs to simultaneously apply hot and cold stimulation to cause a feeling of pain in a small region, such as a fingertip and a facial area, a hot stimulating region and a cold stimulating region where the respective hot and cold stimulation are applied by the device are relatively distant from a hot stimulation site and a cold stimulation site on the skin. This makes it difficult to causing a person to feel pain.

To address the above, a technical means according to a first aspect is adopted. In other words, in the first aspect, a thermoelectric conversion module includes: a first thermoelectric conversion element group that includes at least one first thermoelectric member and at least one second thermoelectric member, the at least one first thermoelectric member including a first conductivity-type semiconductor, the at least one second thermoelectric member including a second conductivity-type semiconductor; a second thermoelectric conversion element group that includes at least one third thermoelectric member and at least one fourth thermoelectric member, the at least one third thermoelectric member including the first conductivity-type semiconductor, the at least one fourth thermoelectric member including the second conductivity-type semiconductor; a first substrate connected to an upper side of the first thermoelectric conversion element group and the second thermoelectric conversion element group; and a second substrate connected to a lower side of the first thermoelectric conversion element group and the second thermoelectric conversion element group. The at least one first thermoelectric member and the at least one second thermoelectric member are electrically connected to each other by a first current path, the at least one third thermoelectric member and the at least one fourth thermoelectric member are electrically connected to each other by a second current path, and the first current path is insulated from the second current path. With this aspect, the size of the thermoelectric conversion module can be reduced because the two types of thermoelectric conversion element groups are sandwiched by common substrates. In addition, selecting an appropriate location for each thermoelectric conversion element group makes it possible to increase flexibility in the layout of the regions corresponding to the respective thermoelectric conversion element groups.

In a second aspect, the thermoelectric conversion module further includes: a first element connecting pad disposed on a surface of the first substrate; and a second element connecting pad disposed on a surface of the second substrate. The second element connecting pad is connected to the at least one first thermoelectric member, the at least one second thermoelectric member, the at least one third thermoelectric member, and the at least one fourth thermoelectric member. With this aspect, the thermoelectric members are directly connected to the second element connecting pad, and the size of the thermoelectric conversion module can be reduced.

In a third aspect, the first substrate is connected to the at least one first thermoelectric member, the at least one second thermoelectric member, the at least one third thermoelectric member, and the at least one fourth thermoelectric member.

In a fourth aspect, in a plan view, a first area size of a first region where the first thermoelectric conversion element group is disposed differs from a second area size of a second region where the second thermoelectric conversion element group is disposed. With this aspect, the area size of each of the two types of regions having a difference in temperature can be set in a haptic device in accordance with human skin sensation.

In a fifth aspect, the first area size is smaller than the second area size. With this aspect, a haptic device can create a realistic feeling of pain in accordance with human skin sensation.

In a sixth aspect, the second area size is at least 1.5 and at most 5 times the first area size. With this aspect, a haptic device can create a realistic feeling of pain in accordance with human skin sensation.

In a seventh aspect, the first thermoelectric conversion element group is used for heat absorption and the second thermoelectric conversion element group is used for heat dissipation. With this aspect, the first region of the haptic device can be used for cold stimulation, the second region of the haptic device can be used for hot stimulation.

In an eighth aspect, a metal layer is continuously provided on a bottom surface of the second substrate across a boundary between a region opposite the first region and a region opposite the second region, and a first wiring connecting pad and a second wiring connecting pad are disposed on the first substrate, the first wiring connecting pad and the second wiring connecting pad separating the first thermoelectric conversion element group and the second thermoelectric conversion element group from each other. With this aspect, efficiency of dissipating heat from the metal layer to outside can be improved, and haptic performance of a haptic device can be improved.

In a ninth aspect, at least a portion of a surrounding region of the first region and at least a portion of a surrounding region of the second region are along a side of the first substrate or a side of the second substrate. With this aspect, a haptic device can create a realistic feeling of pain in accordance with human skin sensation.

In a 10th aspect, a portion except for the portion that is along the side of the first substrate or the side of the second substrate in the surrounding region of the first region is surrounded by the second region. With this aspect, wiring of a haptic device can be kept compact in size and thus a downsized haptic device can be provided.

In an 11th aspect, the first substrate or the second substrate is provided with a first positive electrode pad that is electrically connected to the at least one first thermoelectric member, a first negative electrode pad that is electrically connected to the at least one second thermoelectric member, a second negative electrode pad that is electrically connected to the at least one third thermoelectric member, and a second positive electrode pad that is electrically connected to the at least one fourth thermoelectric member. With this aspect, power can be supplied from an external power source and the thermoelectric conversion module can be operated as a haptic device.

In a 12th aspect, the first positive electrode pad, the first negative electrode pad, the second negative electrode pad, and the second positive electrode pad are disposed along a side of the first substrate or a side of the second substrate. This aspect makes operations for providing wiring for supplying power from an external power source more convenient.

In a 13th aspect, when current flows into the first positive electrode pad and the second positive electrode pad, and flows out from the first negative electrode pad and the second negative electrode pad, a temperature of the first thermoelectric conversion element group decreases to a temperature lower than a temperature of the second thermoelectric conversion element group. With this aspect, the first region functions as a region for cold stimulation, and the second region functions as a region for hot stimulation in a haptic device.

In a 14th aspect, the first conductivity-type semiconductor is an N-type semiconductor and the second conductivity-type semiconductor is a P-type semiconductor.

In a 15th aspect, a closest distance between the first thermoelectric conversion element group and the second thermoelectric conversion element group is greater than a distance between the at least one first thermoelectric member and the at least one second thermoelectric member. This aspect clearly distinguishes a difference in temperature between the first region and the second region and improves haptic performance of a haptic device.

In a 16th aspect, a distance between the first thermoelectric conversion element group and the second thermoelectric conversion element group is less than a distance between the at least one third thermoelectric member and the at least one fourth thermoelectric member. This aspect clearly distinguishes a difference in temperature between the first region and the second region and improves haptic performance of a haptic device.

In a 17th aspect, the distance between the first thermoelectric conversion element group and the second thermoelectric conversion element group is at least 0.1 mm and at most 2.0 mm. This aspect clearly distinguishes a difference in temperature between the first region and the second region and improves haptic performance of a haptic device.

In a 18th aspect, a sum of a total number of the at least one third thermoelectric member and a total number of the at least one fourth thermoelectric member is greater than or equal to a sum of a total number of the at least one first thermoelectric member and a total number of the at least one second thermoelectric member. This aspect enhances a heating capacity and improves haptic performance of a haptic device.

In a 19th aspect, a first temperature sensing sensor is disposed in the first region of the first substrate or the second substrate, and a second temperature sensing sensor is disposed in the second region of the first substrate or the second substrate. This aspect improves accuracy of temperature simulation of the thermoelectric conversion module.

In a 20th aspect, the thermoelectric conversion module further includes an extended portion that extends out from an end of at least one of the first substrate or the second substrate. The first substrate and the second substrate are film-like substrates. This aspect makes it possible to reduce person-hours for individually connecting extended wiring in a conventional technique. Furthermore, the structure according to this aspect has wiring patterns that are bound together, and a first constriction is formed by narrowing the pattern width to a width that is necessary for wiring. This makes the extended portion flexible.

In a 21st aspect, the extended portion includes a third region and a fourth region, and a first width of the third region is wider than a second width of the fourth region, the third region being close to the first substrate or the second substrate, the fourth region being farther from the first substrate or the second substrate than the third region, the first width and the second width each being a width in a direction perpendicular to a longitudinal direction of the extended portion. This aspect ensures flexibility and strength of the extended portion.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1A is a top-view schematic diagram illustrating an overall configuration of a thermoelectric conversion module according to Embodiment 1;

FIG. 1B is a schematic cross-sectional view of the overall configuration of the thermoelectric conversion module according to Embodiment 1;

FIG. 1C is a bottom-view schematic diagram of the overall configuration of the thermoelectric conversion module according to Embodiment 1;

FIG. 1D is a detailed schematic cross-sectional view of the overall configuration of the thermoelectric conversion module according to Embodiment 1; and

FIG. 2 is a schematic diagram of an overall configuration of a thermoelectric conversion module according to Embodiment 2.

### DETAILED DESCRIPTION OF THE EMBODIMENTS

### Embodiment 1

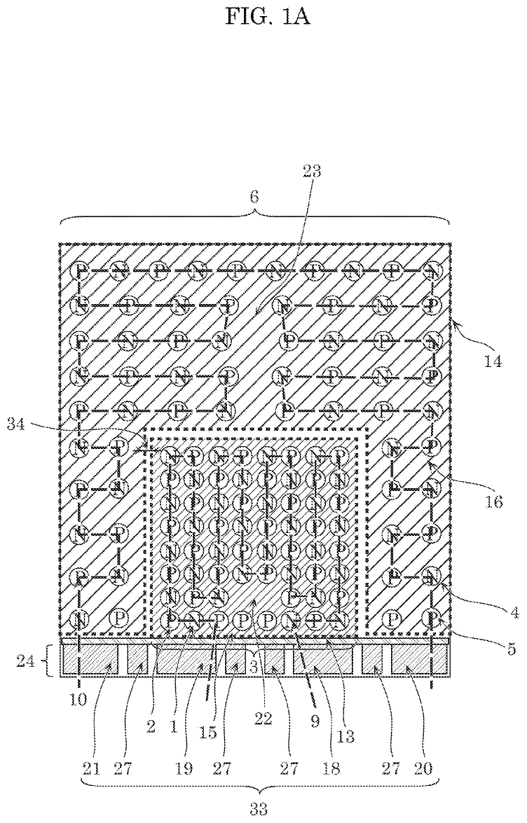

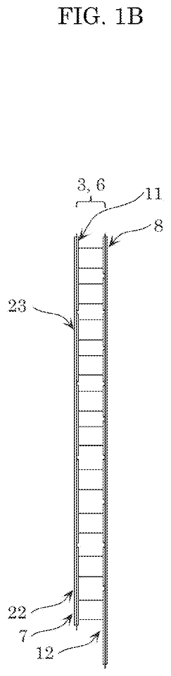

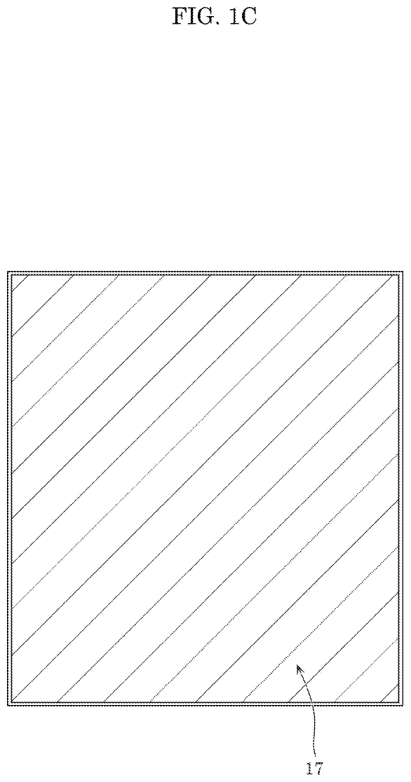

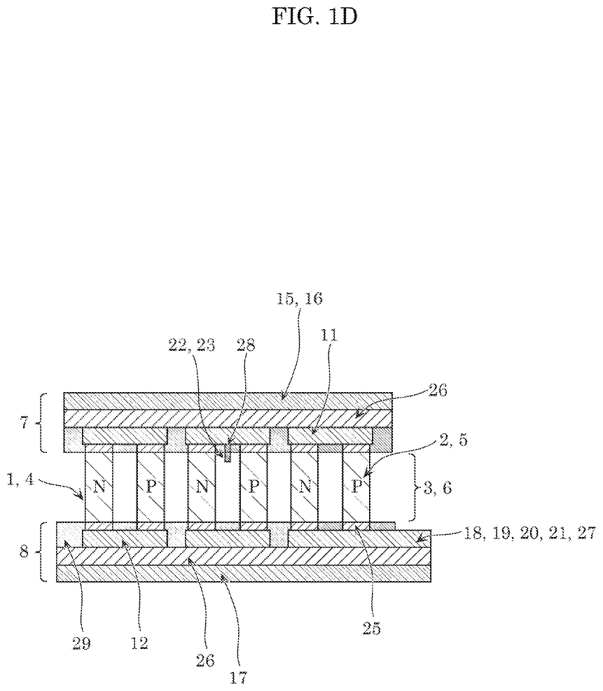

The following describes a thermoelectric conversion module according to Embodiment 1 of the present disclosure with reference to FIGS. 1A to 1D.

FIGS. 1A to 1D illustrate an overall configuration of the thermoelectric conversion module. FIG. 1A is a top-view schematic diagram, FIG. 1B is a schematic cross-sectional view, and FIG. 1D is another schematic cross-sectional view of the thermoelectric conversion module.

The thermoelectric conversion module according to the present embodiment mainly includes: first thermoelectric conversion element group 3 that includes at least one first thermoelectric member 1 and at least one second thermoelectric member 2, the at least one first thermoelectric member 1 including a first conductivity-type semiconductor, the at least one second thermoelectric member 2 including a second conductivity-type semiconductor; second thermoelectric conversion element group 6 that includes at least one third thermoelectric member 4 and at least one fourth thermoelectric member 5, the at least one third thermoelectric member 4 including the first conductivity-type semiconductor, the at least one fourth thermoelectric member 5 including the second conductivity-type semiconductor; first substrate 7 connected to an upper side of first thermoelectric conversion element group 3 and second thermoelectric conversion element group 6; and second substrate 8 connected to a lower side of first thermoelectric conversion element group 3 and second thermoelectric conversion element group 6.

First thermoelectric conversion element group 3 includes an array of a plurality of first thermoelectric members 1 and second thermoelectric members 2 that are alternately arranged. First thermoelectric members 1 and second thermoelectric members 2 are connected to first substrate 7 and second substrate 8 so that first thermoelectric members 1 and second thermoelectric members 2 are electrically connected by first current path 9 through first element connecting pad 11, second element connecting pad 12, and solder 25. Second thermoelectric conversion element group 6 includes an array of third thermoelectric members 4 and fourth thermoelectric members 5 that are alternately arranged. Third thermoelectric members 4 and fourth thermoelectric members 5 are connected to first substrate 7 and second substrate 8 so that third thermoelectric members 4 and fourth thermoelectric members 5 are electrically connected by second current path 10 through first element connecting pad 11, second element connecting pad 12, and solder 25. First current path 9 and second current path 10 are isolated from each other. The number and arrangement of the thermoelectric members can be selected arbitrarily according to a property required for the thermoelectric conversion module.

In the present embodiment, N-type semiconductors including a bismuth-tellurium (Bi—Te) based compound are used as first thermoelectric members 1 and third thermoelectric members 4, and P-type semiconductors including a bismuth-tellurium (Bi—Te) based compound are used as second thermoelectric members 2 and fourth thermoelectric members 4. Note that semiconductors including a thermoelectric material other than the Bi—Te based compound may also be used as the thermoelectric members. For example, an iron-silicon based compound semiconductor or a cobalt-antimony based compound semiconductor may be used.

In first substrate 7, first element connecting pad 11 is formed on base 26. First element connecting pad 11 is connected by first thermoelectric members 1, second thermoelectric members 2, third thermoelectric members 4, fourth thermoelectric members 5, and solder 25. On the back side of first substrate 7, first wiring connecting pad 15 and second wiring connecting pad 16 are formed to separate first thermoelectric conversion element group 3 and second thermoelectric conversion element group 6.

In second substrate 8, second element connecting pad 12 and external wiring connecting pads 33 are continuously formed on base 26. Second element connecting pad 12 is connected by first thermoelectric members 1, second thermoelectric members 2, third thermoelectric members 4, and fourth thermoelectric members 5, and solder 25. On the back side of second substrate 8, metal layer 17 is formed as a wiring connecting pad. Metal layer 17 includes a region including first thermoelectric conversion element group 3 and a region including second thermoelectric conversion element group 6 that are continuously formed.

Regarding base 26, a resin film having flexibility and having a thermally and electrically insulating property may be selected. For example, a polyimide-based or aramid-based resin may be selected as a resin that is sufficiently strong and resistant to heat, even though it is thin.

In the structure according to the present embodiment, a first area size of first region 13 where first thermoelectric conversion element group 3 is disposed differs from a second area size of second region 14 where second thermoelectric conversion element group 6 is disposed. In particular, when the thermoelectric conversion module is used as a haptic device in haptic, beauty, and health applications, increasing the area size of the hot stimulating region larger than the area size of the cold stimulating region makes it possible to change the first area size of first region 13 and the second area size of second region 14 to specifications of a thermoelectric conversion module that can accurately transmit hot and cold information including hot sensation to a fingertip, because the number of hot receptors is less than the number of cold receptors. In the present embodiment, first region 13 is smaller than second region 14 to use first region 13 for cold stimulation and second region 14 for hot stimulation. Note that the second area size may be at least 1.5 at least 1.5 times and at most 5 times the first area size. If the second area size is less than 1.5 times, the sensitivity for hot stimulation in second region 14 is less than the sensitivity for cold stimulation in first region 13 and it is not desirable as a haptic device. If the second area size is greater than five times the first area size, the sensitivity for cold stimulation in first region 13 is less than the sensitivity for hot stimulation in second region 14, and it is not desirable as a haptic device. In the present embodiment, the second area size is three times as large as the first area size.

On first substrate 7, first wiring connecting pad 15 in first region 13 and second wiring connecting pad 16 in second region 14 are separated from each other. Such separation allows formation of a temperature control region that can control first wiring connecting pad 15 in first region 13 and second wiring connecting pad 16 in second region 14 independently from each other.

First region 13 is used for cooling and second region 14 is used for heating. In particular, when the thermoelectric conversion module is used as a haptic device in haptic, beauty, and health applications, increasing the area size of the hot stimulating region larger than the area size of the cold stimulating region makes it possible to accurately transmit hot and cold information including hot sensation to a fingertip, because the number of hot receptors is less than the number of cold receptors. In the present embodiment, first region 13 is smaller than second region 14 to use first region 13 for cold stimulation and second region 14 for hot stimulation.

Moreover, second element connecting pad 12 of second substrate 8 is separated into first region 13 and second region 14. Metal layer 17 is continuously formed on the bottom surface across a boundary of a region opposite first region 13 and a region opposite second region 14. Using a continuous metal layer makes it possible to efficiently exhaust heat of first region 13 from metal layer 17 on the back side.

Regarding the shapes of first region 13 and second region 14, second region 14 has a u-shape and is arranged around first region 13 so that three sides of first region 13 are surrounded by second region 14. Surrounding first region 13 by the u-shaped second region 14 makes it possible to collect external wiring connecting pads 33 in one direction. However, the shapes can be changed according to the area size of the area where external wiring connecting pads 33 are provided and the direction of attaching a power source.

As illustrated in FIG. 1A, at least a portion of a surrounding region of first region 13 and at least a portion of a surrounding region of second region 14 are along a side of first substrate 7 or a side of second substrate 8. A portion except for the portion that is along the side of first substrate 7 or the side of second substrate 8 in the surrounding region of first region 13 is surrounded by second region 14.

First element connecting pad 11 of first substrate 7, second element connecting pad 12 of second substrate 8, first wiring connecting pad 15 of first substrate 7, and second wiring connecting pad 16 of first substrate 7 each have an electrode pattern that is patterned by etching a conductive metal layer, such as copper, into an electrode pattern to electrically connect the thermoelectric members. First element connecting pad 11 and second element connecting pad 12 form an electrode circuit that connects the thermoelectric members in series, and are connected to first positive electrode pad 18, first negative electrode pad 19, second negative electrode pad 20, and second positive electrode pad 21, each of which supplies power. One end of each of first element connecting pad 11 and second element connecting pad 12 is connected to a positive terminal of a direct-current power source, and the other end of each of first element connecting pad 11 and second element connecting pad 12 is connected to a negative terminal of the direct-current power source. Regarding first region 13, first positive electrode pad 18 is electrically connected to first thermoelectric members 1, and first negative electrode pad 19 is electrically connected to second thermoelectric members 2. Regarding second region 14, second positive electrode pad 21 is electrically connected to third thermoelectric members 4 and second negative electrode pad 20 is electrically connected to fourth thermoelectric members 5. First positive electrode pad 18, first negative electrode pad 19, second positive electrode pad 21, and second negative electrode pad 20 are collected in extended portion 24 of second substrate 8. Regarding the forms of first region 13 and second region 14, the power terminals are provided in the same direction in view of downsizing the module.

Here, first positive electrode pad 18, first negative electrode pad 19, second negative electrode pad 20, and second positive electrode pad 21 may be provided on first substrate 7 or second substrate 8. As illustrated in FIG. 1A, first positive electrode pad 18, first negative electrode pad 19, second negative electrode pad 20, and second positive electrode pad 21 may be formed along a side of first substrate 7 or a side of second substrate 8.

First region 13 can be used for cooling and second region 14 can be used for heating by causing the current to flow into first positive electrode pad 18 and second positive electrode pad 21 and flow out from first negative electrode pad 19 and second negative electrode pad 20. As a result, on first substrate 7, the surface of first wiring connecting pad 15 in first region 13 is cooled down, and the surface of second wiring connecting pad 16 in second region 14 is heated to create regions having different temperatures on the surface of first substrate 7. The heat absorbing portion and the heat dissipating portion in first region 13 and second region 14 may be changed and used depending on the usage.

First substrate 7 has gap distance 34 between the electrodes to minimize the heat flowing from second region 14 (heating portion) to first region 13 (cooling portion) and create a difference in surface temperature between first wiring connecting pad 15 in first region 13 and second wiring connecting pad 16 in second region 14. The distance between first thermoelectric conversion element group 3 and second thermoelectric conversion element group 6 may be at least 0.1 mm and at most 2.0 mm, and gap distance 34 between first thermoelectric member 1 and second thermoelectric member 2 may be greater than or equal to 0.5 mm. If the distance and the gap are less than the above values, more heat flows in and the performance of the thermoelectric conversion module deteriorates. In the present embodiment, the closest distance between first thermoelectric conversion element group 3 and second thermoelectric conversion element group 6 is 1.25 mm, and gap distance 34 between first thermoelectric member 1 and second thermoelectric member 2 is 0.5 mm. Here, the shortest distance between first thermoelectric conversion element group 3 and second thermoelectric conversion element group 6 may be greater than the distance between first thermoelectric member 1 and second thermoelectric member 2. The distance between first thermoelectric conversion element group 3 and second thermoelectric conversion element group 6 may be less than the distance between third thermoelectric member 4 and fourth thermoelectric member 5. The sum of the total number of third thermoelectric members 4 and the total number of fourth thermoelectric members 5 may be greater than or equal to the sum of the total number of first thermoelectric members 1 and the total number of second thermoelectric members 2.

If a hot stimulating region that is less sensitive is given higher priority as a haptic device, the total numbers of first thermoelectric members 4 and second thermoelectric members 5 of the heating portion in second region 14 can be increased compared with the cooling portion in first region 13. This emphasizes the difference in the surface temperature between first wiring connecting pad 15 in first region 13 and second wiring connecting pad 16 in second region 14.

On first substrate 7 and second substrate 8, sensor signal wiring pad 27 is formed on extended portion 24 in addition to the electrode circuit, which connects first thermoelectric members 1, second thermoelectric members 2, third thermoelectric members 4, and fourth thermoelectric members 5 in series. Sensor signal wiring pad 27 inputs and outputs signals between i) an external device and ii) temperature sensing sensor 22 and temperature sensing sensor 23 (temperature sensing sensor 22 and temperature sensing sensor 23 are thermistors, for example). For example, temperature sensing sensor 22 and temperature sensing sensor 23 are chip elements, and are soldered to sensor connecting pad 28. Temperature sensing sensor 22 and temperature sensing sensor 23 are disposed on first substrate 7. Temperature sensing sensor 22 and temperature sensing sensor 23 detect the temperature of first substrate 7 accurately, and are used to control energization of the thermoelectric conversion module.

### Embodiment 2

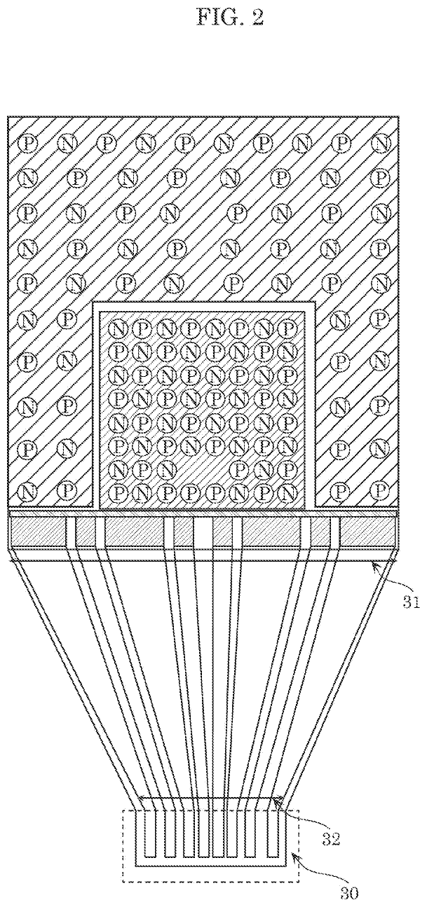

Next, a thermoelectric conversion module according to Embodiment 2 of the present disclosure will be described with reference to FIG. 2. FIG. 2 is a top-view schematic diagram of the thermoelectric conversion module in Embodiment 2.

As with Embodiment 1, first substrate 7 and second substrate 8 have flexibility. First positive electrode pad 18 and first negative electrode pad 19 for first region 13, second positive electrode pad 21 and second negative electrode pad 20 for second region 14, and sensor signal wiring pad 27, which are collected in extended portion 24 of second substrate 8, are further extended in the longitudinal direction. First substrate 7 and second substrate 8 may be film-like substrates to have flexibility, for example. Furthermore, extended portion 24 may extend out from an end of at least one of first substrate 7 or second substrate 8. The extended end portion of second substrate 8 is narrowed to width 32 that matches connector 30. Specifically, width 31 perpendicular to the longitudinal direction of the extended portion in the region where the thermoelectric members are located is 20 mm, whereas width 32 of the extended end portion is 10 mm. Narrowing the width of the extended wiring ensures flexibility. This eliminates a need for soldering a lead wire.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

What is claimed is:

1. A thermoelectric conversion module, comprising:
a first thermoelectric conversion element group that includes at least one first thermoelectric member and at least one second thermoelectric member, the at least one first thermoelectric member including a first conductivity-type semiconductor, the at least one second thermoelectric member including a second conductivity-type semiconductor;
a second thermoelectric conversion element group that includes at least one third thermoelectric member and at least one fourth thermoelectric member, the at least one third thermoelectric member including the first conductivity-type semiconductor, the at least one fourth thermoelectric member including the second conductivity-type semiconductor;
a first substrate connected to an upper side of the first thermoelectric conversion element group and the second thermoelectric conversion element group; and
a second substrate connected to a lower side of the first thermoelectric conversion element group and the second thermoelectric conversion element group, wherein
the at least one first thermoelectric member and the at least one second thermoelectric member are electrically connected to each other by a first current path,
the at least one third thermoelectric member and the at least one fourth thermoelectric member are electrically connected to each other by a second current path, and
the first current path is insulated from the second current path.

2. The thermoelectric conversion module according to claim 1, further comprising:
a first element connecting pad disposed on a surface of the first substrate; and
a second element connecting pad disposed on a surface of the second substrate, wherein
the second element connecting pad is connected to the at least one first thermoelectric member, the at least one second thermoelectric member, the at least one third thermoelectric member, and the at least one fourth thermoelectric member.

3. The thermoelectric conversion module according to claim 2, wherein
the first substrate is connected to the at least one first thermoelectric member, the at least one second thermoelectric member, the at least one third thermoelectric member, and the at least one fourth thermoelectric member.

4. The thermoelectric conversion module according to claim 1, wherein
in a plan view, a first area size of a first region where the first thermoelectric conversion element group is disposed differs from a second area size of a second region where the second thermoelectric conversion element group is disposed.

5. The thermoelectric conversion module according to claim 4, wherein
the first area size is smaller than the second area size.

6. The thermoelectric conversion module according to claim 5, wherein
the second area size is at least 1.5 times and at most 5 times the first area size.

7. The thermoelectric conversion module according to claim 4, wherein
the first thermoelectric conversion element group is used for heat absorption and the second thermoelectric conversion element group is used for heat dissipation.

8. The thermoelectric conversion module according to claim 4, wherein
a metal layer is continuously provided on a bottom surface of the second substrate across a boundary between a region opposite the first region and a region opposite the second region, and
a first wiring connecting pad and a second wiring connecting pad are disposed on the first substrate, the first wiring connecting pad and the second wiring connecting pad separating the first thermoelectric conversion element group and the second thermoelectric conversion element group from each other.

9. The thermoelectric conversion module according to claim 5, wherein
at least a portion of a surrounding region of the first region and at least a portion of a surrounding region of the second region are along a side of the first substrate or a side of the second substrate.

10. The thermoelectric conversion module according to claim 9, wherein
a portion except for the portion that is along the side of the first substrate or the side of the second substrate in the surrounding region of the first region is surrounded by the second region.

11. The thermoelectric conversion module according to claim 1, wherein
the first substrate or the second substrate is provided with a first positive electrode pad that is electrically connected to the at least one first thermoelectric member, a first negative electrode pad that is electrically connected to the at least one second thermoelectric member, a second negative electrode pad that is electrically connected to the at least one third thermoelectric member, and a second positive electrode pad that is electrically connected to the at least one fourth thermoelectric member.

12. The thermoelectric conversion module according to claim 11, wherein
the first positive electrode pad, the first negative electrode pad, the second negative electrode pad, and the second positive electrode pad are disposed along a side of the first substrate or a side of the second substrate.

13. The thermoelectric conversion module according to claim 12, wherein
when current flows into the first positive electrode pad and the second positive electrode pad, and flows out from the first negative electrode pad and the second negative electrode pad, a temperature of the first thermoelectric conversion element group decreases to a temperature lower than a temperature of the second thermoelectric conversion element group.

14. The thermoelectric conversion module according to claim 13, wherein
the first conductivity-type semiconductor is an N-type semiconductor and the second conductivity-type semiconductor is a P-type semiconductor.

15. The thermoelectric conversion module according to claim 4, wherein
a closest distance between the first thermoelectric conversion element group and the second thermoelectric conversion element group is greater than a distance between the at least one first thermoelectric member and the at least one second thermoelectric member.

16. The thermoelectric conversion module according to claim 15, wherein
a distance between the first thermoelectric conversion element group and the second thermoelectric conversion element group is less than a distance between the at least one third thermoelectric member and the at least one fourth thermoelectric member.

17. The thermoelectric conversion module according to claim 16, wherein
the distance between the first thermoelectric conversion element group and the second thermoelectric conversion element group is at least 0.1 mm and at most 2.0 mm.

18. The thermoelectric conversion module according to claim 3, wherein
a sum of a total number of the at least one third thermoelectric member and a total number of the at least one fourth thermoelectric member is greater than or equal to a sum of a total number of the at least one first thermoelectric member and a total number of the at least one second thermoelectric member.

19. The thermoelectric conversion module according to claim 4, wherein
a first temperature sensing sensor is disposed in the first region of the first substrate or the second substrate, and a second temperature sensing sensor is disposed in the second region of the first substrate or the second substrate.

20. The thermoelectric conversion module according to claim 1, further comprising:
an extended portion that extends out from an end of at least one of the first substrate or the second substrate, wherein
the first substrate and the second substrate are film-like substrates.

21. The thermoelectric conversion module according to claim 20, wherein
the extended portion includes a third region and a fourth region, and a first width of the third region is wider than a second width of the fourth region, the third region being close to the first substrate or the second substrate, the fourth region being farther from the first substrate or the second substrate than the third region, the first width and the second width each being a width in a direction perpendicular to a longitudinal direction of the extended portion.
